(19) United States
(12) Patent Application Publication
(10) Pub. No.: US 2005/0088711 A1
(43) Pub. Date: Apr. 28, 2005

(54) Scanning device with preview

(76) Inventor: Stuart W. Daniel, Lexington, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 10/692,709

(22) Filed: Oct. 24, 2003

(51) Int. Cl. H04N 1/04; G03F 3/10

(52) U.S. Cl. 358/527; 358/474

(57) ABSTRACT

A scanning device including a housing, a scanning component at least partially received in the housing for optically scanning a document and providing an electronic version of the document, and a preview screen cooperatively coupled with the housing. The preview screen is coupled to the scanning component such that the electronic version of the document can be visually displayed on the preview screen to provide a preview of the document. The scanning device further includes an interactive component cooperatively coupled with the housing which can receive user input based upon the preview of the document.

### TECHNICAL FIELD

The present invention is directed to a scanning device, and more particularly, to a scanning device which can display a preview version of a scanned document.

### BACKGROUND

Optical scanning devices, or devices which include optical scanning components, are widely used by businesses and personal users for scanning and transmitting documents and other information. Such scanning devices may electronically scan the document. The output or processed output of the scanning device may be provided as an electronic version of the document that can be further processed or manipulated. For example, the electronic version of the scanned document may be printed, exported or sent to a network, computer or other device, sent via a facsimile transmission, etc. However, many scanning devices do not provide the user an opportunity to preview the electronic version of the scanned document prior to such further processing to ensure that the document has been properly scanned.

For example, users may place documents to be scanned on an input tray in the incorrect orientation (i.e., face down instead of face up, or vice versa), may omit a page of the document, may orient the pages of the document in a width-wise instead of length-wise orientation (or vice versa), etc. Scanning devices which do not allow a preview of the document after scanning may cause the electronic version of the document to be sent for further processing without allowing a user to detect the problem with the electronic version. Furthermore, a user may desire to modify the electronic version before the electronic version is sent for further processing.

Accordingly, there is a need for a scanning device which can display a preview version of the document, and which can enable a user to modify the electronic version of the document.

### SUMMARY

In one embodiment, the invention is a scanning device which can display a preview version of a scanned document. Furthermore, in one embodiment, the scanning device may include an interactive component or unit which can allow a user to modify the previewed version of the scanned document and/or the electronic version of the scanned document.

In particular, in one embodiment, the invention is a scanning device including a housing, a scanning component at least partially received in the housing for optically scanning a document and providing an electronic version of the scanned document, and a preview screen cooperatively coupled with the housing. The preview screen is coupled to the scanning component such that the electronic version of the document can be visually displayed on the preview screen to provide a preview of the document. The scanning device further includes an interactive component cooperatively coupled with at least one of the preview screen and the housing which can receive user input based upon the preview of the document. Other objects and advantages of the present invention will be apparent from the following description and the accompanying drawings.

### BRIEF DESCRIPTION OF THE DRAWINGS

FIG. 1 is a front perspective view of one embodiment of the scanning device of the present invention;

FIG. 2 is a block diagram illustrating various components of the scanning device of FIG. 1;

FIG. 3 is another block diagram illustrating various components of the scanning device of FIG. 1;

FIG. 4 is schematic representation or a “screen shot” of the graphical user interface of the scanning device of FIG. 1;

FIG. 5 is a schematic representation or a “screen shot” of the graphical user interface of FIG. 3, with the image rotated 90 degrees; and

FIG. 6 is a schematic representation or a “screen shot” of the graphical user interface of FIG. 1, illustrating various selectable functions of the scanning device.

### DETAILED DESCRIPTION

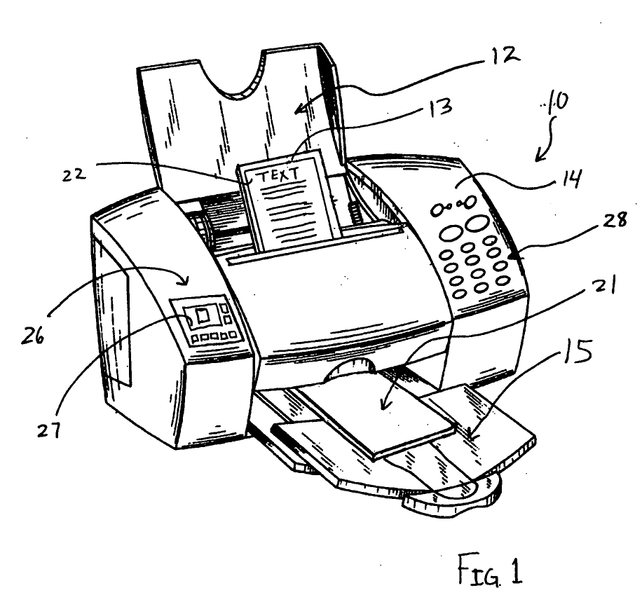

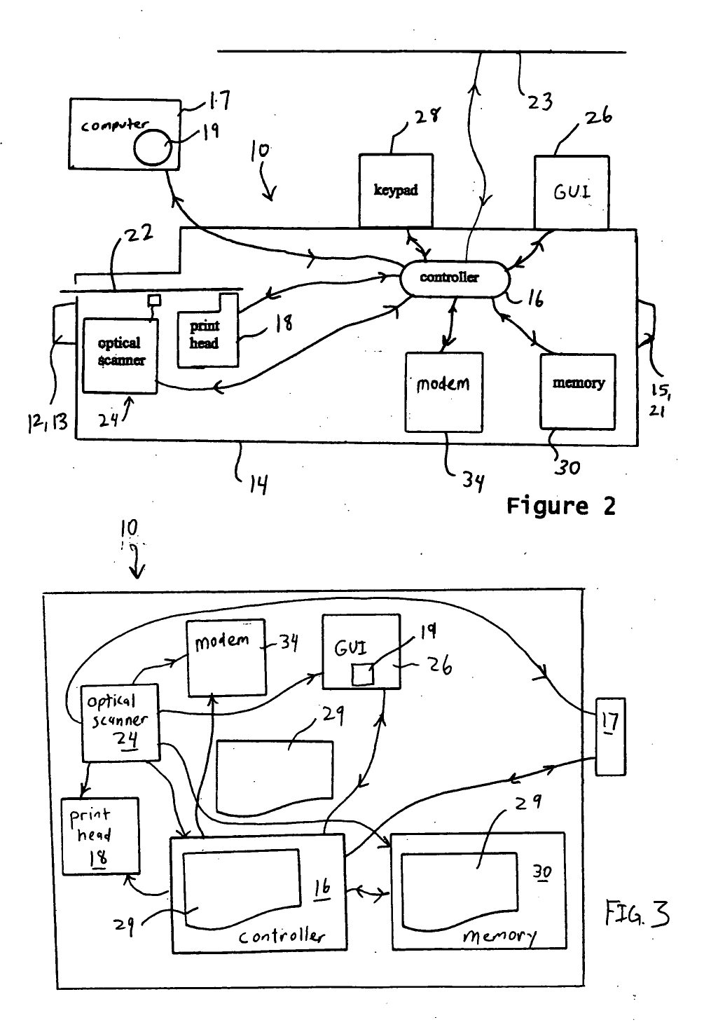

As shown in FIGS. 1 and 2, in one embodiment the scanning device, generally designated 10, may include a housing 14 which may house, store and/or support components of the scanning device 10. The scanning device 10 may include a scanning means, such as an optical scanner or scanning component 24, cooperatively coupled with, contiguous with, integrated into, located in or supported by the housing 14. The optical scanner 24 may be able to determine visual properties of a document 22 which has been scanned and generate an output or scan data, such as data or a data signal corresponding to the visual properties of the document 22. FIG. 2 schematically illustrates the document 22 positioned to be scanned by the optical scanner 24. The optical scanner 24 may be operatively coupled to a controller, processor or CPU (herein referred to as a controller 16). In an alternative embodiment, the controller may be an integral component of the optical scanner. Once the document 20 is scanned, the scan data or data signal generated by the optical scanner 24 may then be sent to the controller 16 for further processing. The controller 16 may in turn include or be coupled to a memory means or memory 30, which can include a hard drive, ROM, RAM, or other memory devices.

The scanning device 10 may be coupled to a computer 17 and/or a network 23. The network 23 can be a LAN, WAN, or other connection system between computers or other devices that allows communication and the flow of data therebetween. The scanning device 10 may also include a data modem 34, which can interface with a telecommunications line, computer 17, or network 23 and can function as an incoming facsimile processing means and an outgoing facsimile processing means.

In one embodiment, the scanning device 10 is, includes, or is part of, a multifunction device such as, for example, a multifunction facsimile machine/copier/scanner/printer. Thus the scanning device 10 may include printing means, such as a print head 18, operatively coupled to the controller 16. The print head 18 may be able to print documents, text, photos, drawings, etc. onto various media in response to command, data and print information sent to the controller 16 and/or print head 18. The command, data and print information provided to the print head 18 may be sent from a variety of devices or components, including the optical scanner 24, the controller 16, the computer 17, the network 23, modem 34, or from some other source.

FIG. 2 schematically illustrates the print head 18 for printing on a document 22. As noted above, FIG. 2 also schematically illustrates the optical scanner 24 for optically scanning the document 22. However, it should be understood that the optical scanner 24 and print head 18 may not necessarily operate on, or be able to operate on, the same document 22 at the same time.

As noted above, the scanning device 10 may include a modem 34 which may be or include incoming facsimile processing means which can receive facsimiles and facsimile transmissions in a standard manner. For example the modem 34 may convert incoming facsimile transmissions into print commands/data to be printed by the print head 18, or sent to the controller 16, computer 17 or network 23. The modem 34 may also be or include outgoing facsimile processing means so that the scanning device 10 can transmit outgoing facsimiles and facsimile transmission in a standard manner. For example the modem 34 may convert optically scanned documents/data, or data supplied from the controller 16, computer 17 (such as a host computer), network 23, or optical scanner 24 into outgoing facsimile transmissions.

The scanning device 10 may include a scan input tray 13 for storing paper, documents, or other media to be scanned or faxed (i.e. to be processed by the optical scanner 24). The scanning device 10 may include a scan output tray 21 for storing papers, documents, or other media scanned, printed or output from the facsimile machine 10 via the scan/fax input tray 13. The scanning device 10 may also include a print input tray 12 for storing paper or other media 22 to be printed upon by the print head 18 in the manner of a standard printer, and a print output tray 15 for storing papers, documents, or other media output by the scanning device 10 via the print input tray 12. However, if desired, the scanning device 10 may also include only a single input tray and a single output tray.

The scanning device 10 may include an interactive graphical display unit or graphical user interface (“GUI”) 26 which can receive information and data and can visually display information, data, documents, text, etc. The GUI 26 may include a display screen or display area 42 such as a monitor, LCD display, or the like. The GUI 26 may also be able to receive inputs from a user. For example, when the display screen 42 is a LCD screen or display, the LCD screen may also operate as a touch pad 27 that is responsive to pressure or touch from a user. The GUI may also include a controller.

The GUI 26 may be relatively small and sized to fit onto the housing 14 of the scanning device 10. Thus, for example, the GUI 26 may be on the order of 2″×2″, 4″×4″, or 6″×6″. The GUI 26 may be directly coupled to the optical scanner 24, and/or indirectly coupled to the optical scanner 24, such as, for example, via the controller 16. FIG. 3 illustrates both direct and indirect connections between the GUI 26 and the optical scanner 24.

The scanning device 10 may also include an interactive component or unit, such as a standard numerical or alphanumeric keypad 28, which can also receive inputs from a user. The keypad 28 may be integrated and connected to the various components of the scanning device 10 in the same manner as the GUI 26. Both the GUI 26 and the keypad 28 may be cooperatively coupled with, contiguous with, located on, or integrated into, the housing 14, and may be coupled to the controller 16 so that inputs from a user can be sent to the controller 16 or other components via the GUI 26 and/or keypad 28. The GUI and keypad 28 may also be cooperatively coupled together. In an alternative embodiment, the controller may be an integral component of the interactive component.

FIG. 1 illustrates a document 22 located on the scanning input tray 13. The document 22 may include more than one page, although only a single page is shown in FIG. 1. After the document 22 is moved into a position such that it can be scanned and is scanned by the optical scanner 24 (FIG. 2), the output of the optical scanner 24 or scan data may be sent to the controller 16. The controller 16 may assemble, manipulate, or process the output of the optical scanner 24 to create an electronic version 29 of the document 22 (FIG. 3). The electronic version 29 of the document 22 can be an electronic file which can be edited by software or a computer or stored in electronic form. However, the electronic version 29 of the document 22 may also or instead be created by the optical scanner 24, or by some other component. As shown in FIG. 3, the output of the optical scanner 24, and or the electronic version 29 of the document 22 may be stored in the memory 30, or elsewhere in the device 10.

After the optical scanner 24 scans the document 22, at least part of the output of the optical scanner 24, such as the electronic version 29 of the document 22, may then be sent to the GUI 26. The output sent from the controller 16 to the GUI 26 can take a variety of forms, and may include some or all of the scan data sent from the optical scanner 24, or a processed or filtered output of the scan data sent from the optical scanner 24, or the electronic version 29 of the document 22, or a processed or filtered version of the electronic version 29, etc. The GUI 26 can transform the received data into a visual display. For example, the controller 16 and/or GUI 26 may be or include an image-processing component that can generate low-resolution images suitable for display on the GUI 26. In this manner, the GUI 26 may operate as a preview screen such that a preview 19 of the scanned data, such as the electronic version 29 of the document 22 can be visually displayed on the GUI 26.

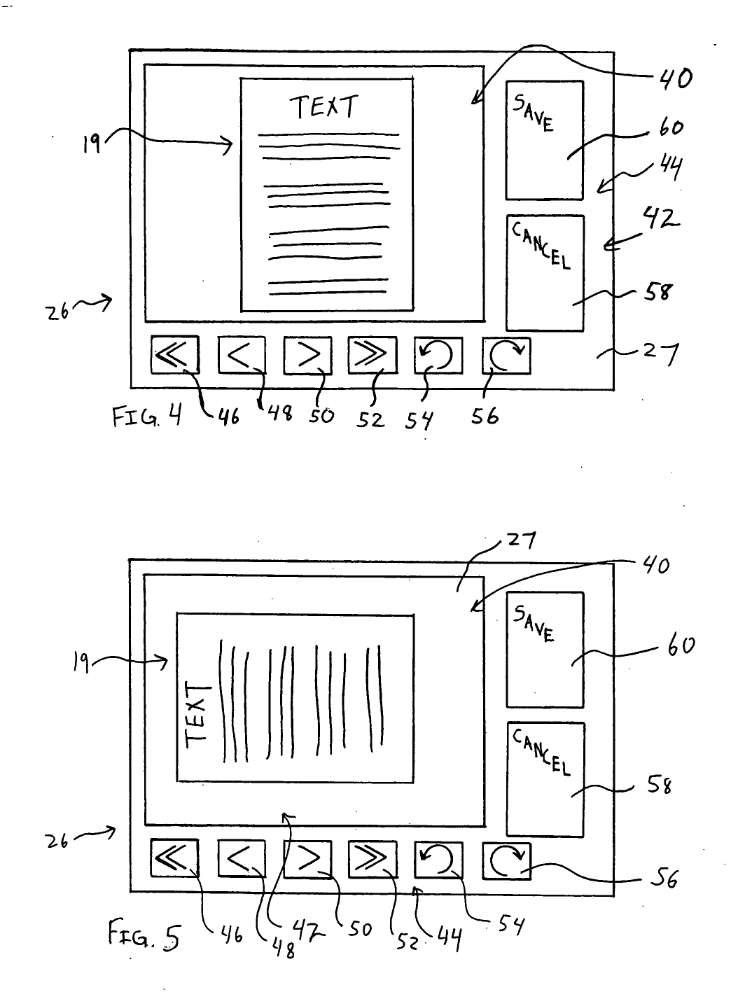

As shown in FIG. 4, the preview 19 of the scanned data displayed on the GUI 26 may provide data to the user regarding the electronic version 29 of the document 22. In particular, the user may be able to determine whether the wrong side of the document 22 has been scanned, whether the electronic version 29 of the document 22 or preview 19 of the scanned data needs to be rotated or otherwise edited, or whether other corrective action or modifications are required.

In the illustrated embodiment, the display area 42 of the GUI 26 may include a preview portion 40 and a control portion 44. For example, the display area 42 may have a pixel arrangement of 640×480, the preview portion 40 may have a pixel arrangement of 480×360 pixels and the control portion 44 may comprise the remaining pixels of the display area 42. Accordingly, the preview 19 of the scanned data displayed on the GUI 26 may be of a lower resolution than the entire electronic version 29 of the document 22 (which can, for example, have a resolution of about 5100×6600 pixels). However, the GUI 26 may have sufficient resolution to provide feedback to the user as to the general orientation and data of the electronic version 29 of the document 22 or other output of the optical scanner 24. The GUI 26 may also be capable of simultaneously displaying multiple pages of the scanned document thereon. For example, the GUI 26 may be able to display 2-10 or more pages of the scanned document so that a user can quickly preview multiple pages of the document without having to individually index through the pages.

The preview portion 40 of the display area 42 may be utilized to display the preview 19 of the scanned data, and the control portion 44 may be used to provide a plurality of control buttons or selectable areas which can be pressed, selected, manipulated, activated or operated (hereinafter collectively referred to as “operated”) by a user (e.g., by pressing the corresponding button). A user can operate one or more of the buttons to change, customize, update or modify (hereinafter collectively referred to as “modify”) the preview 19 of the document 22 and/or the electronic version 29 of the document 22. For example, in the embodiment illustrated in FIGS. 4 and 5 the control portion 44 of the display area 42 may have buttons 46, 48, 50, 52, 54, 56, 58, 60. Furthermore, instead of, or in addition to, utilizing or providing the control portion 44 of the display area 42, the buttons of the keypad 28 may be operated to modify the preview 19 of the document 22 and/or the electronic version 29 of the document 22.

When a user operates the buttons of the control portion 44 and/or keypad 28, such operation may cause a modification in the preview 19 of the document and/or the electronic version 29 of the document (i.e., stored in the controller 16, memory 30, or elsewhere). The use of the GUI 26 to display selectable areas or touch-sensitive “buttons” enables a wide variety of shapes and functions of “buttons” to be dynamically displayed on the GUI 26 for operation by the user. Instead of being touch sensitive buttons, a “cursor” or other similar movable component (such as a box, pointer or function which causes different ones of the buttons to be highlighted or identified) may be utilized to operate the buttons. Further, the configuration and orientation of buttons or selectable surfaces illustrated herein are only one of an almost unlimited configuration and orientation of buttons or selectable surfaces which can be utilized in the present invention.

In the example shown in FIGS. 4 and 5, the control portion 44 may include a set of “navigation” buttons 46, 48, 50 and 56 which may be utilized to scroll through various pages of the document 22. For example, button 46 may be operated to jump back a predetermined number of preceding pages of the document 22 (or to the first page of the document 22), and button 48 may be operated to display the immediately preceding page of the document 22. Similarly, button 54 may be operated to move to a predetermined subsequent page of the document 22 (or to the last page of the document 22), and button 50 may be operated to move to the next subsequent page of the document 22.

The “rotation” buttons or functions 54, 56 may be operated to rotate the preview 19, electronic versions 29, and/or other output of the optical scanner 24. For example, button 54 may be operated to rotate the preview 19 or electronic versions 29 of the document 22 in a counterclockwise direction, and button 56 may be operated to rotate the preview 19 or electronic versions 29 of the document 22 in the clockwise direction. Thus, for example, as shown in FIG. 4, if a user desires to rotate the preview 19 or electronic versions 29 of the document 22 90° in a counterclockwise direction, button 54 would be operated.

As shown in FIG. 5, after the button 54 is operated, the preview 19 of the document 22 is displayed on the preview portion 40 rotated 90° in a counterclockwise direction. Thus, when a user operates one of the rotations buttons 54, 56, or other selectable function of the control portion 44, the preview 19 of the document 22 may be correspondingly modified, as shown in comparison of FIGS. 4 and 5.

Alternately, or in addition, when one of the buttons or selectable functions is operated by a user the electronic version 29 of the document 22 (i.e., the electronic version 29 stored in the controller 16, memory 30 or elsewhere) and/or other output of the optical scanner 24 may also be modified to accommodate the desired modification. Thus, pressing or operating one of the rotation button 54, 56 or selecting a function by a user may cause both the preview 19 of the document 22 and the electronic version 29 of the document 22 (or other output of the optical scanner 24) to be modified in the desired manner. In order to accommodate the desired rotation or other modification, a flag indicating the desired rotation or other modification may be inserted into the electronic version 29 or other output of the optical scanner 24, or the electronic version 29 or other output may otherwise be modified to accommodate the desired rotation or other modification.

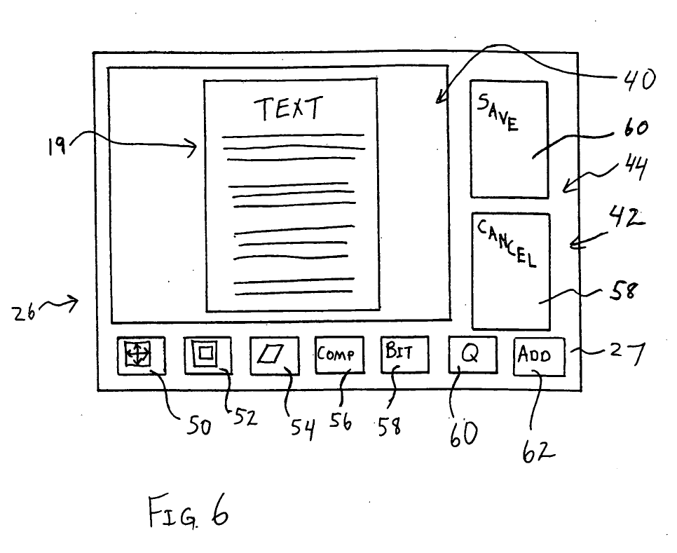

A wide variety of functions, besides rotation of the document, may be provided as options to a user to manipulate/modify the document via the GUI 26. For example, FIG. 6 illustrates another set of modification options which may be presented to a user. However, a wide variety of modification options beyond those specifically discussed herein may be used without departing from the scope of the invention. As shown in FIG. 6, the GUI 26 may have a “crop” button 50 which can be operated to allow a user to manually crop the image displayed on the GUI 26. Various methods for cropping an image may be utilized, including drawing an area to be cropped on the pressure sensitive GUI 26, selecting an initial origin and using a stylus or finger or arrow keys to alter the crop box size, etc. Furthermore, the scanning device 10 may include an “auto crop” function which can be activated by operating a button in which the crop lines or outer boundaries of the document may be suggested by the scanning device 10 and the suggested crop lines may be able to be approved by the user.

The GUI 26 may display a “change resolution” button or function 52 which can be operated by user to change the resolution (or image size) of the preview 19 or electronic version 29 of the document 22 or other output of the optical scanner 24. In this manner, the image dimensions may be increased or reduced, with a corresponding change in quality and file size.

Button 54 may be a “deskew” button or function which can be operated to deskew or reduce the skew of the preview 19 or electronic version 29 of the document 22 or other output of the optical scanner 24. Various ways of implementing the desired deskew may be implemented, including selecting a corner of the document to remain stationary and then allowing user to rotate the preview 19 or electronic version 29 of the document 22 or other output of the optical scanner 24 about that corner.

Button 56 may be an “image compression” button or function which can be operated to allow a user to change the image compression of the preview 19 or electronic version 29 of the document 22 or other output of the optical scanner 24. In particular, when a user operates button 56, the user may be able to select different image compression schemes, or alter the parameters of the current compression scheme of an electronic version 29 of the document 22. In this manner, changing the image compression may allow user to alter the size of the electronic version 29 of the document 22.

Button 58 may be a “change bit depth” button or function which can be operated to allow a user to change the bit depth of an electronic version 29 of the document 22. For example, the user may be able to convert 24 bit RGB to grayscale (and vice versa), change grayscale to 1-bit binary black/white (and vice versa), etc.

Button 60 may be an “image processing” button or function which can be operated to allow a user to adjust the image quality of the preview 19 and/or electronic version 29 by a variety of well-known functions including sharpening, inverting the colors of and/or smoothing the image. A user may also be able to invert the preview 19 or electronic version 29 of the document 22 or other output of the optical scanner 24 by reversing the black/white configuration (or other colors) of the document.

Button 62 may be an “add page” button or function which can be operated to allow a user to insert additional pages into the document. In particular, after the document 22 has been scanned and previewed, a user may notice that one or more of the pages of the scanned document 22 has been omitted. A user may then be able to direct the optical scanner 24 to scan the missing page(s) and insert the newly scanned page into the electronic version 29 of the document 22 at the desired location. For example, the newly added page can be inserted as the first or the last page of the electronic version 29 of the document 22, or as an intermediate page of the electronic version 29 of the document 22. The add page button 62 may also be utilized to add additional pages when the document to be scanned is two-sided, and a user notices that the back sides of the pages of the document have not been scanned.

Once a document 22 has been scanned and previewed, and, if desired, modified, a user may then operate the “confirm” or “save” button or function 60 of the GUI 26. If not previously modified, the electronic version 29 of the document 22 or other output of the optical scanner 24 and/or the preview 19 of the document 22 may then be modified to accommodate the changes input by the user.

The electronic version 29 of the scanned document 22 or other output of the optical scanner 24 may then be sent for further processing by, for example, being sent to another computer 17, sent to the print means 18 for printing, sent to the modem 34, send to the network 23 for further processing, printing, viewing, etc. Alternately, the user may operate a “cancel” button or function 58, which will not cause the electronic version 29 of the document 22 to be sent or further transmitted or exported, and the user may be returned to an upper level menu on the GUI 26. Operating or activating the cancel function 58 may also cause the preview 19 to be removed from the GUI 26, and/or the electronic version 29 erased from the controller 16 and memory 30. If desired, the user may then provide a new document to be scanned, previewed and processed as described above.

Having described the invention in detail and by reference to the preferred embodiments, it will be apparent that modifications and variations thereof are possible without departing from the scope of the invention.

1. A scanning device comprising:
a housing;
a scanning component at least partially received in said housing for optically scanning a document and providing an electronic version of said document;
a preview screen cooperatively coupled with said housing and coupled to said scanning component such that said electronic version of said document can be visually displayed on said preview screen; and
an interactive component cooperatively coupled with at least one of said housing and said preview screen which can receive user input based upon said preview of said document.

2. The device of claim 1, wherein said preview screen and said interactive component are components of a graphical interface unit.

3. The device of claim 1, wherein said user input indicates acceptance or rejection of said electronic version of said document.

4. The device of claim 1, wherein said device is configured such that if said interactive component receives user input indicating acceptance of said electronic version of said document, said device exports said electronic version of said document.

5. The device of claim 4, wherein said exportation includes exporting said electronic version of said document to at least one of a network, host computer, telecommunications line, and printer.

6. The scanning device of claim 1, wherein said interactive component, in response to input from a user, causes modification of at least one of said preview of said document and said electronic version of said document.

7. The device of claim 1, wherein said interactive component includes at least one selectable function which, when selected by a user, causes said preview of said document to be modified or causes said electronic version of said document to be modified.

8. The device of claim 1, further comprising a controller, and wherein said scanning component, said preview screen and said interactive component are coupled to said controller.

9. The device of claim 8, wherein said controller is capable of processing or storing said electronic version of said document.

10. The device of claim 1, wherein said device includes means for connecting to a network to send said electronic version of said document to said network.

11. The device of claim 1, wherein said electronic version of said document includes at least part of an output of said scanning component that is indicative of at least part of the visual properties of said document.

12. The device of claim 1 wherein said device is a multifunction machine.

13. The device of claim 1 wherein said device includes an outgoing facsimile processing means for converting said electronic version of said document into an outgoing facsimile transmission.

14. The device of claim 1, wherein said device includes a print means for printing said electronic version of said document.

15. The device of claim 14, wherein said print means prints documents in response to commands and data signals sent from a computer.

16. The device of claim 1 wherein said device includes an exporting means for sending said electronic version of said document to an external device.

17. The device of claim 1 wherein said scanning component is capable of scanning a multi-page document.

18. The device of claim 17, wherein said preview screen is capable of displaying each page of said electronic version of said multi-page document.

19. The scanning device of claim 1, wherein said interactive component, in response to input from a user, causes modification of at least one of said preview of said document and said electronic version of said document.

20. The device of claim 1 wherein said interactive component includes at least one selectable rotate function which, when selected or operated by a user, causes said preview of said electronic version of said document to rotate or causes said electronic version of said document to be modified to accommodate such desired rotation.

21. The device of claim 1 wherein said interactive component includes at least one selectable crop function which, when selected or operated by a user, causes said preview of said electronic version of said document to be cropped or causes said electronic version of said document to be modified to accommodate such desired cropping.

22. The device of claim 1 wherein said interactive control unit includes at least one selectable change resolution function which, when selected or operated by a user, causes said preview of said electronic version of said document to be change its resolution or causes said electronic version of said document to be modified to accommodate such desired change in resolution.

23. The device of claim 1 wherein said interactive component includes an selectable add page function which, when selected or operated by a user, causes said electronic version of said document to be modified to accommodate an additional scanned page.

24. The device of claim 1 wherein said interactive component includes at least one selectable deskew function which, when selected or operated by a user, causes said preview of said electronic version of said document to be deskewed or causes said electronic version of said document to be modified to accommodate such desired deskewing.

25. The device of claim 1 wherein said interactive component includes at least one selectable image compression function which, when selected or operated by a user, causes said electronic version of said document to change compression schemes or alters the parameters of a compression scheme of said electronic version of said document.

26. The device of claim 1 wherein said interactive component includes at least one selectable alter bit depth function which, when selected or operated by a user, causes said electronic version of said document to change its bit depth.

27. The device of claim 1 wherein said interactive component includes at least one image processing button or selectable image processing function which, when selected or operated by a user, causes said electronic version of said document to be modified.

28. The device of claim 1 wherein said interactive component includes a touch pad configured to receive inputs from a user in response to manual pressure applied to said touch pad.

29. The device of claim 1 wherein said interactive component includes a plurality of selectable functions which can be operated by a user.

30. The scanning device of claim 1 wherein said preview screen and said interactive component are each part of an interactive graphical display unit.

31. A scanning device comprising:
a housing;
a scanning component cooperatively coupled with said housing for optically scanning a document and providing an output that is indicative of at least part of the visual properties of said document;
a memory or controller capable of receiving at least part of said output of said scanning component and storing or processing said at least part of said output as an electronic version of said document;
a preview screen cooperatively coupled with said housing and coupled to said scanning component such that at least part of said output of said scanning component is a preview of said document which can be displayed on said preview screen; and
an interactive component cooperatively coupled with at least one of said housing and said preview screen which, in response to input from a user, can cause modification of at least one of said preview of said document and said electronic version of said document.

32. The device of claim 31, wherein said at least part of said output that can be provided to said preview screen includes at least part of said electronic version of said document.

33. A method for previewing a document on a scanning device having a preview screen and an interactive component comprising the steps of:
scanning a document to generate an output that is indicative of at least part of said document;
forming a preview of said document and an electronic version of said document;
displaying said preview on said preview screen.

34. The method of claim 33, further including the step of receiving input from a user.

35. The method of claim 34, wherein said input indicates rejection or acceptance of said scanned document or of said preview of said document or of said electronic version of said document.

36. The method of claim 34, further including the step of, in response to said input, modifying at least one of said preview of said document and said electronic version of said document.

37. A scanning device comprising:
means for optically scanning a document and providing an electronic version of said document;
means for visually displaying said electronic version of said document on a preview screen; and
means for receiving user input based upon said display of said document.
